(19) United States
(12) Patent Application Publication
(10) Pub. No.: US 2026/0311764 A1
(43) Pub. Date: Oct. 8, 2026

(54) LATERAL CHARGE MIGRATION HANDLING ON EDGE WORDLINES OF A MEMORY DEVICE IN A MEMORY SUB-SYSTEM

(71) Applicant: Micron Technology, Inc., Boise, ID (US)

(72) Inventors: Gary F. Besinga, Boise, ID (US); Michael G. Miller, Boise, ID (US); Tawalin Opastrakoon, Boise, ID (US); Che Chen, Boise, ID (US)

(21) Appl. No.: 19/173,044

(22) Filed: Apr. 8, 2025

(51) Int. Cl. G11C 16/10; G11C 16/08

(52) U.S. Cl. CPC G11C 16/102; G11C 16/08

(57) ABSTRACT

A processing device in a memory system identifies first data associated with a first wordline of a memory device. The first wordline is a data wordline at an edge of a data block of the memory device. The processing device identifies a second wordline adjacent to the first wordline, where the second wordline is a dummy wordline. The processing logic generates second data based on the first data. The second data is associated with a second voltage characteristic corresponding to a first voltage characteristic associated with the first data. The processing logic programs the second data on the second wordline.

### TECHNICAL FIELD

Embodiments of the disclosure relate generally to memory sub-systems, and more specifically, relate to lateral charge migration handling on edge wordlines of a memory device in a memory sub-system.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1 illustrates an example computing system that includes a memory sub-system in accordance with some embodiments of the present disclosure.

FIG. 2 is a block diagram illustrating a wordline configuration of a block in a memory device in accordance with some embodiments of the present disclosure.

FIG. 3 is a flow diagram of an example method to handle lateral charge migration on edge wordlines in accordance with some embodiments of the present disclosure.

FIG. 4 is a block diagram of an example computer system in which embodiments of the present disclosure may operate.

### DETAILED DESCRIPTION

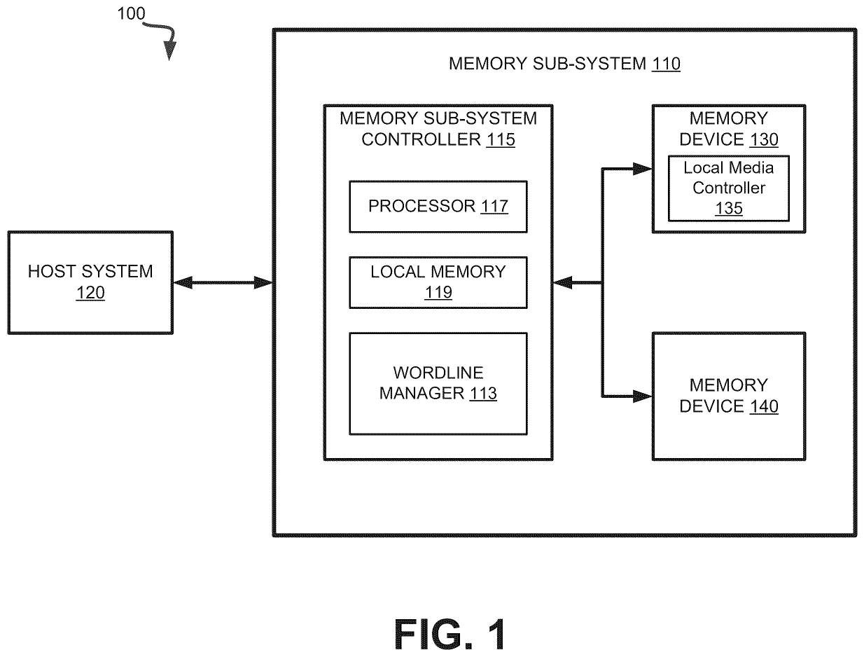

Aspects of the present disclosure are directed to handling lateral charge migration on edge wordlines of a memory device in a memory sub-system. A memory sub-system can be a storage device, a memory module, or a combination of a storage device and memory module. Examples of storage devices and memory modules are described below in conjunction with FIG. 1. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. One example of non-volatile memory devices is a not-and (NAND) memory device. Other examples of non-volatile memory devices are described below in conjunction with FIG. 1. A non-volatile memory device is a package of one or more dies. Each die can include one or more planes. For some types of non-volatile memory devices (e.g., NAND devices), each plane includes of a set of physical blocks. Each block includes of a set of pages. Each page includes of a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1”, or combinations of such values.

A memory device can be made up of bits arranged in a two-dimensional or a three-dimensional grid. Memory cells are formed onto a silicon wafer in an array of columns (also hereinafter referred to as bitlines) and rows (also hereinafter referred to as wordlines). A wordline can have a row of associated memory cells in a memory device that are used with one or more bitlines to generate the address of each of the memory cells. The intersection of a bitline and wordline constitutes the address of the memory cell. A block hereinafter refers to a unit of the memory device used to store data and can include a group of memory cells, a wordline group, a wordline, or individual memory cells. One or more blocks can be grouped together to form separate partitions (e.g., planes) of the memory device in order to allow concurrent operations to take place on each plane. The memory device can include circuitry that performs concurrent memory page accesses of two or more memory planes. For example, the memory device can include multiple access line driver circuits and power circuits that can be shared by the planes of the memory device to facilitate concurrent access of pages of two or more memory planes, including different page types. For ease of description, these circuits can be generally referred to as independent plane driver circuits. Depending on the storage architecture employed, data can be stored across the memory planes (i.e., in stripes). Accordingly, one request to read a segment of data (e.g., corresponding to one or more data addresses), can result in read operations performed on two or more of the memory planes of the memory device.

Certain memory devices in a memory sub-system are arranged in blocks having a number of vertically stacked wordlines associated with the memory cells. A given block, for example, can include a number of wordlines at the bottom of the stack and a number of wordlines at the top of the stack which are not used to store host or system data. These wordlines can be referred to as “dummy wordlines.” The actual data wordlines associated with memory cells used to store host and/or system data can be arranged, for example, in a number of decks between the top and bottom dummy wordlines. Each deck of data wordlines can further be separated by one or more dummy wordlines. Such a memory device can typically program each block starting with the wordlines at the bottom of the stack and finishing at the top of the stack, for example. The data wordlines within each deck that are adjacent to the surrounding dummy wordlines can be referred to as “edge wordlines.”

Some memory devices can be subject to physical phenomena that affect the charge stored in their cells (e.g., charge loss) and consequently, also affect the respective threshold voltages of the cells. These phenomena can arise in a memory array between one or more specified cells and/or wordlines. Examples of such phenomena include lateral charge migration (LCM). LCM is a phenomena where electrons diffuse between wordlines (e.g., electrons move from a wordline of higher voltage to a wordline of lower voltage), changing the voltage of affected wordlines. LCM can be caused by cells in close proximity with strong electric fields causing charge leakage between floating gates (e.g., a polysilicon layer that traps electrons) of adjacent cells. LCM can also be caused by repeatedly reading a cell, which applies an electric field to the target cell and surrounding cells, shifting a stored charge over time. Additional causes of LCM include high temperatures (e.g., that increase electron mobility and accelerate charge movement), prolonged storage (e.g., that provides time for electrons to move to other cells), and/or oxide effects (e.g., degradation of an oxide layer that stores and insulates voltage).

LCM can lead to significant voltage shifts in the cells and/or wordlines. For example, the shift can be sufficient to cause a memory access operation performed on a target cell to switch to a determined sensed state (e.g., a logic state assigned to a cell) other than the one associated with the programming level of the target cell (e.g., a programmed logical ‘1’ state can instead be determined to be a logical ‘0’ state, etc.). Consequently, these physical phenomena can cause a lowering and widening of the voltage distribution associated with a given programming level, (e.g., L1, L2, etc.), and impair the ability to accurately read values from the given programming level.

In certain memory devices, the edge wordlines often experience stronger voltage shifts than other data wordlines due to the voltage difference between the edge wordline and the dummy wordline, which cannot be logically accessed (e.g., cannot be programmed) by a memory subsystem due to hardware configurations of the memory system (e.g., the dummy wordlines are not connected to memory cells capable of storing data, dummy wordlines are not connected to components that can apply the correct voltage to the wordline, such as charge pumps, etc.). As such, the dummy wordline cannot be programmed to be at a similar voltage to the edge wordline, leading to charge leakage caused by the difference in voltages between the edge and dummy wordline.

In some situations, charge loss in a cell due to LCM can be mitigated by programming a wordline adjacent to the wordline experiencing LCM with data of a similar voltage, which reduces disturbance of electrons in wordlines due to similar electric fields. For example, the last programmed wordline in a partially programmed data block can experience LCM due to an adjacent wordline that is empty (e.g., not programmed with data) and thus has a lower voltage than the programmed wordline. The voltage discrepancy between the last programmed wordline and empty wordline create a strong lateral field that causes electrons from the last programmed wordline to drift to the empty wordline, changing the voltage of the last programmed wordline and/or the empty wordline. However, programming the empty wordline with dummy data of a similar voltage can decrease the strength of the lateral field because the voltages of the two wordlines will be similar, reducing the drifting of electrons between the wordlines.

Though dummy wordlines adjacent to edge wordlines may be programmed in a test mode by a local driver, the dummy wordlines cannot be programmed with data of a similar voltage to the edge wordline by a host system. For example, dummy wordlines may not have an assigned memory address in an address space maintained by the host system, preventing dummy wordlines from being accessed and written to by the host system. For example, dummy wordlines may not have a corresponding address in a memory address map of the host system, preventing the host system from requesting access to and/or issuing write requests because the host system does not have a location corresponding to the dummy wordline to send the request to. As such, dummy wordlines cannot be programmed to address the voltage discrepancy with an adjacent edge wordline, causing LCM as electrons from the edge wordline drift to the dummy wordline.

In some systems, when an error is encountered during a read operation (e.g., a hard read failure) with respect to a memory cell (e.g., a target cell), or when a bit error rate (BER) with respect to multiple cells is exceeded, a sequence of error handling operations (or sequence of recovery operations) can be undertaken. This sequence can include performing a corrective read operation. A corrective read operation can include applying one or more adjusted (e.g., compensated) read reference voltages (e.g., voltages offset from a default read reference voltage) to determine the programming state of the target cell (depending on the programming level of an adjacent aggressor cell).

However, a corrective read operation can be a resource intensive approach, depending on the number of additional operations used to determine the modified parameters (e.g., voltage adjustments) to determine a voltage adjustment for a given programming level (e.g., read level offset). Compensation operations can increase the time (e.g., read time) to complete respective corrective read operations, and can significantly delay the transmission of data to the host device. Additionally, some operations that compensate for charge loss phenomena (e.g., LCM) might not be effective in practically improving a desired performance metric (e.g., an increase in reliability, such as a decreased BER, etc.).

Aspects of the present disclosure address the above and other deficiencies by providing a memory sub-system that handles lateral charge migration on edge wordlines of a memory device in the memory sub-system. In one embodiment, processing logic in the memory sub-system can identify data associated with (e.g., programmed to or about to be programmed to) an edge wordline. The processing logic can identify a dummy wordline adjacent to the edge wordline and generate dummy data of a similar voltage to (e.g., within a threshold voltage range of) the data associated with the edge wordline. In some embodiments, the dummy data can be identical to the data associated with the edge wordline. The processing logic can then program the dummy data to the dummy wordline. For example, the dummy wordline can be connected to one or more memory cells capable of storing data, in some embodiments. In other embodiments, the dummy wordline can be connected to one or more hardware components (e.g., voltage drivers, charge pumps, etc.) that allow processing logic to cause a voltage corresponding to the dummy data to be applied to the dummy wordline.

Advantages of the present disclosure include, but are not limited to, mitigating data loss due to LCM in edge wordlines. The system can reduce the frequency of LCM by programming a dummy wordline with data of a similar voltage to an edge wordline, so electrons stored in the edge wordline are less likely to be influenced by the electric field of the dummy wordline, reducing electron drift between the two wordlines. As such, data loss in edge wordlines is reduced due to the reduction in LCM. Additionally, the reduction in voltage shifts reduces the amount of errors during read operations, as the voltage of wordlines are less likely to change, reducing the error handling trigger rate (e.g., the frequency with which an error correction mechanism is activated within a system). The reduction in corrective read operations can save resources (e.g., electric power from voltage adjustments, processing power to perform corrective operations, etc.), which can be allocated to other processes. As such, loss mitigation due to LCM in edge wordlines can reduce the latency of the system by reducing the error handling trigger rate and save resources from corrective operations, which can be allocated to other parts of the system.

FIG. 1 illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to multiple memory sub-systems 110 of different types. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the physical host interface (e.g., PCIe or CXL bus). The physical host interface can provide an interface for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a not-and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 130 can include one or more arrays of memory cells such as SLCs, MLCs, TLCs, QLCs, PLCs or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), not-or (NOR) flash memory, or electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, memory sub-system 110 is a managed memory device, which is a raw memory device 130 having control logic (e.g., local media controller 135) on the die and a controller (e.g., memory sub-system controller 115) for media management within the same memory device package. An example of a managed memory device is a managed NAND (MNAND) device.

The memory sub-system 110 includes a wordline manager 113 that can mitigate data loss from LCM in edge wordlines by programming a dummy wordline adjacent to the edge wordline with data of a similar voltage. In some embodiments, the memory sub-system controller 115 includes at least a portion of the wordline manager 113. In some embodiments, the wordline manager 113 is part of the host system 120, an application, or an operating system. In other embodiments, local media controller 135 includes at least a portion of wordline manager 113 and is configured to perform the functionality described herein.

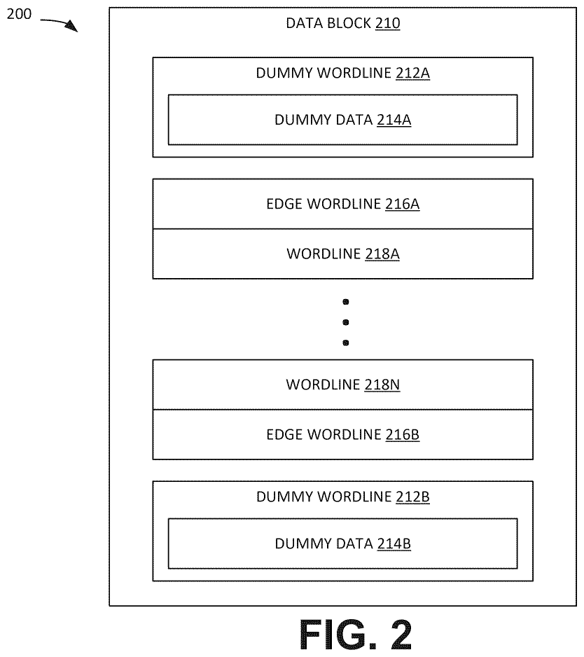

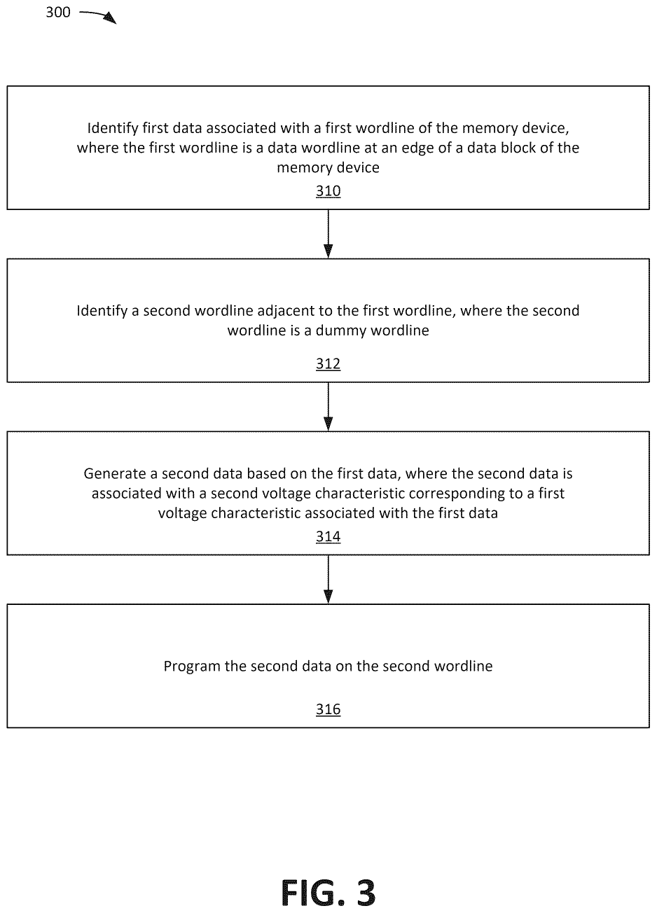

The wordline manager 113 can identify data associated with (e.g., programmed to or about to be programmed to) an edge wordline in a data block. The wordline manager 113 identifies a dummy wordline adjacent to the edge wordline (e.g., using an address table corresponding to the location of each wordline). The wordline manager 113 can determine a voltage of the data associated with the edge wordline (e.g., by calculating the predefined voltage of the data) and generate dummy data (e.g., placeholder and/or nonfunctional data) of a similar voltage to (e.g., with a predefined voltage within a threshold voltage range of) the voltage of the data associated with the edge wordline. The wordline manager 113 then programs the dummy wordline with the dummy data (e.g., by causing a programming voltage corresponding to the dummy data to be applied to the dummy wordline. Further details with regards to the operations of the wordline manager 113 are described below with respect to FIG. 2 and FIG. 3.

FIG. 2 is a block diagram illustrating a wordline configuration of a block in a memory device, in accordance with some embodiments of the present disclosure. As illustrated in FIG. 2, data block 210 can include a number of wordlines (e.g., dummy wordlines 212A and 212B, edge wordlines 216A and 216B, and wordlines 218A-218N) arranged in a vertical stack. Each of the wordlines can be connected to one or more memory cells and can receive control signals (e.g., from wordline manager 113) to perform memory access operations on associated memory cells. Depending on the embodiment, data block 210 can include some other number of wordlines.

In some embodiments, edge wordlines 216A and 216B (herein referred to as edge wordline(s) 216) and wordlines 218A-218N (herein referred to as wordline(s) 218) are data wordlines, which are generally used for storing host data (e.g., data received from the host system 120). Edge wordlines 216 are data wordlines that are located at an edge of a data block (e.g., the top or bottom wordline in the stack of data wordlines. In some embodiments, the processing logic (e.g. wordline manager 113) can determine whether a wordline is an edge wordline based on an address of the wordline. For example, in some embodiments, the wordline manager 113 can determine the row address of a wordline in the memory array, where the row address corresponds to where the wordline is located in the array. The wordline manager 113 can determine whether the wordline is an edge wordline by determining whether the row address indicates whether the wordline is the first or last wordline in the array (e.g., by comparing the row address to the total number of rows in the array and/or maintaining a register that defines the first and last addresses of the array). In other or similar embodiments, the wordline manager 113 can decode the address (e.g., convert a logical row address to a physical location in the memory device) and determine whether the wordline is an edge wordline based on the decoded address. For example, in an array with 64 data wordlines where the data wordlines are numbered from 0 to 63, the wordline manager 113 can determine that a wordline is an edge wordline if the decoded address is 000000 (e.g., 0 in binary) or 111111 (e.g., 63 in binary).

In other or similar embodiments, dummy wordlines 212A and 212B (herein referred to as dummy wordline(s) 212) refers to wordlines that are programmable but generally do not store host data. In some embodiments, dummy wordlines 212 can store dummy data that is of a similar voltage to data stored in edge wordlines 216 so as to prevent LCM due to voltage differences between the edge wordline 216 and dummy wordline 212. Dummy wordlines 212 can be above an edge wordline at the top of the stack (e.g., edge wordline 216A) and/or below an edge wordline at the bottom of the stack (e.g., edge wordline 216B).

In some embodiments, the dummy wordline 212 can be connected (e.g., physically connected to) one or more memory cells that are capable of storing data (e.g., capable of capturing and/or storing charges corresponding to data). For example, in some embodiments, dummy wordlines 212 can be connected to one or more control gates (e.g., an electrode that applies a voltage to control the flow of electrons in and out of a floating gate and/or charge trap) of one or more memory cells, which allows dummy wordlines to receive programming voltages to store data (e.g., dummy data 214). In some embodiments, floating gates (e.g., conductors that trap electrons in a memory cell) and/or charge trap layers (e.g., non-conductive dielectric layers, such as silicon nitride, that trap electrons in a memory cell) can also be included in memory cells connected to the dummy wordline, allowing the dummy wordline to retain the programmed data. In other or similar embodiments, the dummy wordlines 212 can be connected to voltage hardware, such as row decoders (e.g., components that decode a row address and activate a corresponding wordline), voltage drivers (e.g., components that control the voltages applied to wordlines), charge pumps (e.g., components that generate higher voltages for memory operations), and/or voltage regulators (e.g., components that provide stable, controlled voltages) that can apply a program voltage (e.g., a voltage to program data on a wordline) to the dummy wordline.

In some embodiments, the processing logic (e.g., wordline manager 113) can identify data associated with an edge wordline (e.g., edge wordline 216A) and identify a dummy wordline (e.g., dummy wordline 212A) adjacent to the edge wordline. The wordline manager can then generate dummy data (e.g., dummy data 214) of a similar voltage to the data associated with the edge wordline and program the dummy data to the dummy wordline.

FIG. 3 is a flow diagram of an example method 300 to handle lateral charge migration on edge wordlines, in accordance with some embodiments of the present disclosure. The method 300 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 300 is performed by the wordline manager 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 310, the processing logic identifies first data associated with a first wordline of the memory device, where the first wordline is a data wordline at an edge of a data block of the memory device. In some embodiments, wordline manager 113 can identify the first data based on a command (e.g., a write command received from the host system 120) to store data in an available wordline and identifying an edge wordline as available to store the data. In some embodiments, wordline manager 113 can maintain a table that indicates which wordlines are storing data (e.g., by listing wordline addresses for wordlines that have been written to). Based on the table, the wordline manager 113 can identify an empty wordline and determine whether the wordline is an edge wordline (e.g., based on a logical address of the wordline). In other embodiments, the wordline manager 113 can perform an operation to determine if a wordline contains data (e.g., by performing a read operation to determine whether a programmed voltage is detected in the wordline). The wordline manager 113 can iterate through wordlines in the stack and perform the operation to find the first available wordline. The wordline manager can then determine whether the available wordline is an edge wordline (e.g., using the logical address). In other embodiments, the wordline manager 113 can identify the first data by identifying an edge wordline that is storing data. For example, the wordline manager 113 can maintain a table of programmed wordlines, as described above, and determine whether edge wordlines are listed in the table based on the logical address of each wordline, in some embodiments. In other embodiments, the wordline manager 113 can perform an operation on an edge wordline to determine whether the edge wordline has a programming voltage.

At operation 312, the processing logic identifies a second wordline adjacent to the first wordline, where the second wordline is a dummy wordline. For example, in some embodiments, the wordline manager 113 can maintain an address map corresponding to wordlines in the array, including dummy wordlines. Upon determining the address of the edge wordline, the wordline manager 113 can access the address map (e.g., a table indicating how logical addresses correspond to physical locations in memory hardware) to identify the dummy wordline adjacent to the edge wordline (e.g., a dummy wordline with an address indicating that it is adjacent to the edge wordline). In some embodiments, the wordline manager 113 can use address decoding on the address of the dummy wordline and/or edge wordline to determine that the wordlines are adjacent (e.g., by determining whether the decoded addresses are contiguous). As described above, dummy wordlines are wordlines that are generally not used to store host data. In some embodiments, dummy wordlines can be connected to one or more voltage hardware (e.g., memory cells, voltage drivers, charge pumps) that allow the dummy wordline to be programmed with data, as described above with respect to FIG. 2. It should be noted that the terms “first wordline” and “second wordline” are for ease of reference and do not indicate the order and/or position of dummy wordlines and/or edge wordlines. For example, in a data block of stacked wordlines programmed from the bottom of the stack to the top of the stack, the first wordline (e.g., edge wordline) can be the first data wordline in a data block and the second wordline (e.g., dummy wordline) can be located below the first wordline and programmed before the first wordline, in some embodiments. In other embodiments, the first wordline (e.g., edge wordline) can be the last data wordline in the data block and the second wordline (e.g., dummy wordline) can be located above the first wordline and programmed after the first wordline.

At operation 314, the processing logic generates second data based on the first data, where the second data is associated with a second voltage characteristic corresponding to a first voltage characteristic associated with the first data. For example, in some embodiments, the wordline manager 113 can identify a voltage of the first data by reading the programmed voltage level of the edge wordline. In other embodiments, the wordline manager 113 can determine the voltage of the first data by calculating a predefined voltage level corresponding to the state of the data (e.g., the amount and location of logical 0s and 1s in the data). For example, the wordline manager 113 can parse the first data into a series of individual bits (e.g., “0” and “1” ) and determine the position of individual bits (e.g., based on an index of the bit). The wordline manager 113 can then determine the amount of logical 0s and 1s in the data and, in some embodiments, use a table and/or predefined rules that associate voltage levels with data values (e.g., a table mapping a logical 1 to a voltage of 3 volts (V)) to determine the predefined voltage of the first data. Based on the identified and/or calculated voltage of the first data, the wordline manager can generate dummy data with a similar voltage to the first data. For example, in some embodiments the wordline manager 113 can determine a data combination with a predefined voltage that is similar to the first data. In some embodiments, the wordline manager 113 can determine whether a voltage of dummy data is similar to the voltage of the first data by determining whether the voltage of the dummy data is within a threshold range of the voltage of the first data. For example, the wordline manager 113 can determine whether the voltage of the dummy data is within a range of 3 V from the voltage of the first data. If the data is outside of the range, the wordline manager can generate new dummy data, in some embodiments. In other embodiments, the dummy data can be identical to the first data.

At operation 316, the processing logic programs the second data on the second wordline. In some embodiments, programming can include applying a voltage that corresponds to the dummy data (e.g., a voltage level that indicates the logic state of each cell in the wordline) is applied to the dummy wordline. For example, in some embodiments, a dummy wordline can be connected to memory cells (e.g., physically connected to the control gate, or a component that applies voltages to a memory cell) capable of storing charges that represent data. As such, when the voltage is applied to the dummy wordline, the charge can be captured and stored in the memory cells connected to the dummy wordline, programming the dummy wordline with the dummy data. In some embodiments, the dummy wordline can be connected to one or more voltage components, such as voltage drivers, charge pumps, and/or voltage regulators that will apply the voltage to the dummy wordline upon receiving an instruction from the wordline manager 113. In some embodiments, the wordline manager 113 can gang (e.g., simultaneously program) the edge wordline and dummy wordline. For example, the wordline manager 113 can apply the same voltage to the wordlines at the same time using multiple wordline drivers and/or shared control signals that can transmit the same programing command to separate wordline drivers corresponding to each wordline. As such, the wordlines can be programmed with the same data at the same time. In other embodiments, the dummy wordline can be programmed before the edge wordline.

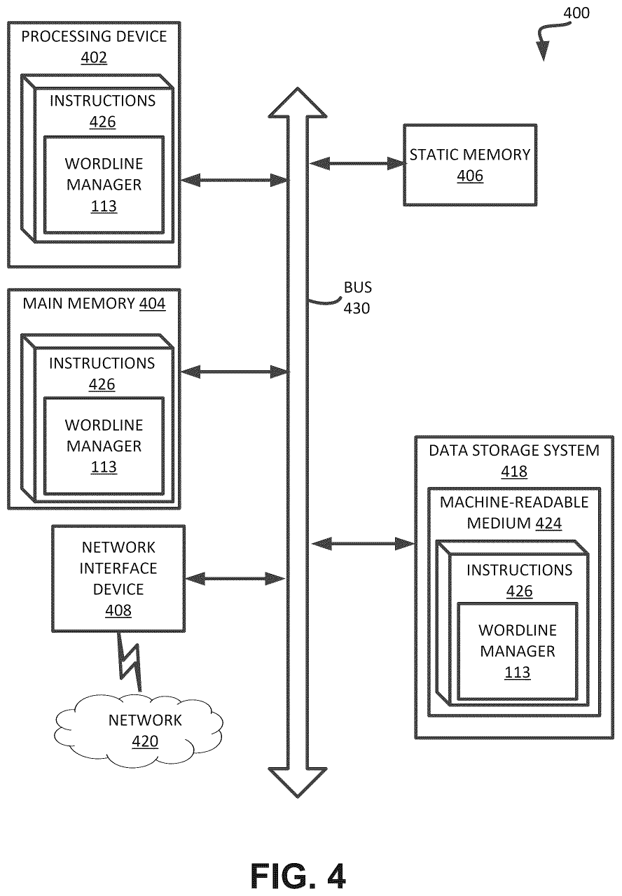

FIG. 4 illustrates an example machine of a computer system 400 within which a set of instructions, for causing the machine to perform any one or more of the methodologies discussed herein, can be executed. In some embodiments, the computer system 400 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the wordline manager 113 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 400 includes a processing device 402, a main memory 404 (e.g., read-only memory (ROM), flash memory, dynamic random access memory (DRAM) such as synchronous DRAM (SDRAM) or RDRAM, etc.), a static memory 406 (e.g., flash memory, static random access memory (SRAM), etc.), and a data storage system 418, which communicate with each other via a bus 430.

Processing device 402 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 402 can also be one or more special-purpose processing devices such as an application specific integrated circuit (ASIC), a field programmable gate array (FPGA), a digital signal processor (DSP), network processor, or the like. The processing device 402 is configured to execute instructions 426 for performing the operations and steps discussed herein. The computer system 400 can further include a network interface device 408 to communicate over the network 420.

The data storage system 418 can include a machine-readable storage medium 424 (also known as a computer-readable medium) on which is stored one or more sets of instructions 426 or software embodying any one or more of the methodologies or functions described herein. The instructions 426 can also reside, completely or at least partially, within the main memory 404 and/or within the processing device 402 during execution thereof by the computer system 400, the main memory 404 and the processing device 402 also constituting machine-readable storage media. The machine-readable storage medium 424, data storage system 418, and/or main memory 404 can correspond to the memory sub-system 110 of FIG. 1.

In one embodiment, the instructions 426 include instructions to implement functionality corresponding to a wordline manager (e.g., the wordline manager 113 of FIG. 1). While the machine-readable storage medium 424 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A system comprising:
a memory device; and
a processing device, operatively coupled to the memory device, to perform operations comprising:
identifying first data associated with a first wordline of the memory device, wherein the first wordline is a data wordline at an edge of a data block of the memory device;
identifying a second wordline adjacent to the first wordline, wherein the second wordline is a dummy wordline;
generating second data based on the first data, wherein the second data is associated with a second voltage characteristic corresponding to a first voltage characteristic associated with the first data; and
programming the second data on the second wordline.

2. The system of claim 1, wherein programming the second data on the second wordline comprises causing a voltage corresponding to the second voltage characteristic to be applied to the second wordline.

3. The system of claim 1, wherein the second data is identical to the first data, and wherein the second voltage characteristic is identical to the first voltage characteristic.

4. The system of claim 1, wherein the processing device is to perform operations further comprising:
programming the first data on the first wordline and the second data on the second wordline concurrently.

5. The system of claim 1, wherein the data block comprises a plurality of wordlines arranged in a vertical stack, wherein the plurality of wordlines comprises a subset of data wordlines to store host data and a subset of dummy wordlines that do not store host data.

6. The system of claim 5, wherein one or more dummy wordlines of the subset of dummy wordlines are arranged above a data wordline of the subset of data wordlines at a top of the stack, and wherein one or more dummy wordlines of the subset of dummy wordlines are arranged below a data wordline of the subset of data wordlines at a bottom of the stack.

7. The system of claim 1, wherein identifying the second wordline further comprises:
maintaining an address map comprising an address associated with the second wordline;
and identifying the address associated with the second wordline.

8. The system of claim 1, wherein generating the second data further comprises:
identifying the first voltage characteristic associated with the first data; and
generating the second data with the second voltage characteristic, wherein the second voltage characteristic is within a threshold range of the first voltage characteristic.

9. A method comprising:
identifying first data associated with a first wordline of a memory device, wherein the first wordline is a data wordline at an edge of a data block of the memory device;
identifying a second wordline adjacent to the first wordline, wherein the second wordline is a dummy wordline;
generating second data based on the first data, wherein the second data is associated with a second voltage characteristic corresponding to a first voltage characteristic associated with the first data; and
programming the second data on the second wordline.

10. The method of claim 9, wherein programming the second data on the second wordline comprises causing a voltage corresponding to the second voltage characteristic to be applied to the second wordline.

11. The method of claim 9, wherein the second data is identical to the first data, and wherein the second voltage characteristic is identical to the first voltage characteristic.

12. The method of claim 9, further comprising:
programming the first data on the first wordline and the second data on the second wordline concurrently.

13. The method of claim 9, wherein the data block comprises a plurality of wordlines arranged in a vertical stack, wherein the plurality of wordlines comprises a subset of data wordlines to store host data and a subset of dummy wordlines that do not store host data.

14. The method of claim 13, wherein one or more dummy wordlines of the subset of dummy wordlines are arranged above a data wordline of the subset of data wordlines at a top of the stack, and wherein one or more dummy wordlines of the subset of dummy wordlines are arranged below a data wordline of the subset of data wordlines at a bottom of the stack.

15. The method of claim 9, wherein identifying the second wordline further comprises:
maintaining an address map comprising an address associated with the second wordline;
and identifying the address associated with the second wordline.

16. The method of claim 9, wherein generating the second data further comprises:
identifying the first voltage characteristic associated with the first data; and
generating the second data with the second voltage characteristic, wherein the second voltage characteristic is within a threshold range of the first voltage characteristic.

17. A non-transitory computer-readable medium comprising instructions that, when executed by a processing device, cause the processing device to perform operations further comprising:
identifying first data associated with a first wordline of a memory device, wherein the first wordline is a data wordline at an edge of a data block of the memory device;
identifying a second wordline adjacent to the first wordline, wherein the second wordline is a dummy wordline;
generating second data based on the first data, wherein the second data is associated with a second voltage characteristic corresponding to a first voltage characteristic associated with the first data; and
programming the second data on the second wordline.

18. The non-transitory computer-readable medium of claim 17, wherein programming the second data on the second wordline comprises causing a voltage corresponding to the second voltage characteristic to be applied to the second wordline.

19. The non-transitory computer-readable medium of claim 17, wherein the second data is identical to the first data, and wherein the second voltage characteristic is identical to the first voltage characteristic.

20. The non-transitory computer-readable medium of claim 17, wherein the operations further comprise:
programming the first data on the first wordline and the second data on the second wordline concurrently.
